(19) United States
(12) Patent Application Publication
(10) Pub. No.: US 2026/0033126 A1
(43) Pub. Date: Jan. 29, 2026

(54) LIGHT-EMITTING ELEMENT, DISPLAY DEVICE, METHOD FOR PRODUCING LIGHT-EMITTING ELEMENT, AND METHOD FOR PRODUCING DISPLAY DEVICE

(71) Applicant: Sharp Display Technology Corporation, Kameyama City, Mie (JP)

(72) Inventor: Yuma YAGUCHI, Sakai City, Osaka (JP)

(21) Appl. No.: 18/997,961

(22) PCT Filed: Aug. 9, 2022
(86) PCT No.: PCT/JP2022/030466

§ 371 Date: Jan. 23, 2025

(51) Int. Cl. H10K 50/115; H10K 50/14; H10K 71/15; H10K 71/20; H10K 102/00

(52) U.S. Cl. CPC H10K 50/115; H10K 50/14; H10K 71/15; H10K 71/221; H10K 71/231; H10K 2102/331; H10K 2102/351

(57) ABSTRACT

An emission layer provided in a light-emitting element includes a nanoparticle layer including a nanoparticle, and a graphene layer being in contact with the nanoparticle layer, and including a graphene oxide having a functional group capable of coordinating with the nanoparticle.

### TECHNICAL FIELD

The present disclosure relates to a light-emitting element, a display device, and a method for producing the light-emitting element, and a method for producing the display device.

### BACKGROUND ART

In recent years, various display devices provided with light-emitting elements have been developed. In particular, a display device provided with quantum-dot light-emitting diodes (QLEDs) or organic light-emitting diodes (OLEDs) has attracted much attention because it can achieve low power consumption, thickness reduction, high image quality, and other advantages.

Patent Literature 1 describes forming a hole injection layer or a hole transport layer using graphene oxide. Patent Literature 2 describes forming an anode electrode using graphene. Patent Literature 3 describes using graphene as semiconductor nanoparticles.

### CITATION LIST

### Patent Literatures

Patent Literature 1: Japanese Unexamined Patent Application Publication No. 2019-157129
Patent Literature 2: Japanese Unexamined Patent Application Publication No. 2020-191287
Patent Literature 3: Japanese Unexamined Patent Application Publication No. 2021-5479

### SUMMARY

### Technical Field

However, Patent Literatures 1 to 3 merely describe forming any one of a hole injection layer, a hole transport layer, an electrode layer, and an emission layer provided in a light-emitting element by the use of graphene; here, the graphene layer formed by using graphene and a nanoparticle layer including nanoparticles are not formed in close contact. Hence, the light-emitting elements described in Patent Literatures 1 to 3 exhibit poor packing capability (adhesion) between the graphene layer and nanoparticle layer; in the nanoparticle layer, solvent resistance and gas barrier capability, both of which are the effects of graphene layers, cannot be sufficiently obtained. Furthermore, since the graphene layer and the nanoparticle layer are not formed in close contact in Patent Literatures 1 to 3, as earlier described, the graphene does not affect the solution dispersibility of the nanoparticles included in the nanoparticle layer, thereby failing to subject the nanoparticle layer to patterning, which can be performed by changing the solution dispersibility of the nanoparticles by the use of graphene.

One aspect of the present disclosure has been made in view of this problem. It is an object of the aspect to provide a light-emitting element, a display device, a method for producing the light-emitting element, and a method for producing the display device that can achieve high solvent resistance and high gas barrier capability, and that enable a nanoparticle layer including nanoparticles to undergo patterning.

### Solution to Problem

To solve the above problem, a light-emitting element in the present disclosure includes the following:
an emission layer; and
a charge functional layer,
wherein at least one of the emission layer and the charge functional layer includes
   a nanoparticle layer including a nanoparticle, and
   a graphene layer being in contact with the nanoparticle layer, and including a graphene oxide having a functional group capable of coordinating with the nanoparticle.

To solve the above problem, a display device in the present disclosure includes the light-emitting element.

To solve the above problem, a method for producing a light-emitting element in the present disclosure includes the following:
a nanoparticle-layer formation step of forming a nanoparticle layer by using a nanoparticle solution containing a nanoparticle and a first solvent;
at least one of a first graphene-layer formation step and a second graphene-layer formation step each being a step of forming a graphene layer by using a graphene oxide solution containing a second solvent and a graphene oxide having a functional group capable of coordinating with the nanoparticle, the first graphene-layer formation step being anterior to the nanoparticle-layer formation step, the second graphene-layer formation step being posterior to the nanoparticle-layer formation step; and
a nanoparticle-layer patterning step of patterning the nanoparticle layer into a predetermined shape,
wherein in the nanoparticle-layer formation step and the second graphene-layer formation step, both of which are performed after the first graphene-layer formation step, the nanoparticle layer and the graphene layer are formed so as to be in contact at least partly.

To solve the above problem, a method for producing a display device in the present disclosure includes the method for producing the light-emitting element.

### Advantageous Effect of Disclosure

The aspects of the present disclosure can provide a light-emitting element, a display device, a method for producing the light-emitting element, and a method for producing the display device that can achieve high solvent resistance and high gas barrier capability, and that enable a nanoparticle layer including nanoparticles to undergo patterning.

### BRIEF DESCRIPTION OF DRAWINGS

FIG. 1 is a plan view of the schematic configuration of a display device according to a first embodiment.

FIG. 2 is a cross-sectional view of the schematic configuration of a display region of the display device according to the first embodiment.

FIG. 3 is a cross-sectional view of the schematic configuration of a red light-emitting element included in the display device according to the first embodiment.

FIG. 4 is a cross-sectional view of the schematic configuration of a green light-emitting element included in the display device according to the first embodiment.

FIG. 5 is a cross-sectional view of the schematic configuration of a blue light-emitting element included in the display device according to the first embodiment.

FIG. 6 illustrates an example of a red emission layer included in the red light-emitting element of the display device according to the first embodiment.

FIG. 7 illustrates another example of the red emission layer that can be included in the red light-emitting element of the display device according to the first embodiment.

FIG. 8 illustrates an example of a hole transport layer that can be included in the red light-emitting element of the display device according to the first embodiment.

FIG. 9 illustrates an example of an electron transport layer that can be included in the red light-emitting element of the display device according to the first embodiment.

FIG. 10 illustrates part of a step of forming the red emission layer, which is included in the red light-emitting element of the display device according to the first embodiment illustrated in FIG. 4.

FIG. 11 illustrates the remaining process step of forming the red emission layer, which is included in the red light-emitting element of the display device according to the first embodiment illustrated in FIG. 4.

FIG. 12 illustrates part of an emission-layer formation step, according to a second embodiment, of forming the red emission layer, which is included in the red light-emitting element of the display device according to the first embodiment illustrated in FIG. 4.

FIG. 13 illustrates the remaining emission-layer formation step, according to the second embodiment, of forming the red emission layer, which is included in the red light-emitting element of the display device according to the first embodiment illustrated in FIG. 4.

FIG. 14 illustrates part of an emission-layer formation step, according to a third embodiment, of forming the red emission layer, which is included in the red light-emitting element of the display device according to the first embodiment illustrated in FIG. 4.

FIG. 15 illustrates the remaining emission-layer formation step, according to the third embodiment, of forming the red emission layer, which is included in the red light-emitting element of the display device according to the first embodiment illustrated in FIG. 4.

FIG. 16 illustrates an emission-layer formation step, according to a fourth embodiment, of forming the red emission layer, which is included in the red light-emitting element of the display device according to the first embodiment illustrated in FIG. 4.

### DESCRIPTION OF EMBODIMENTS

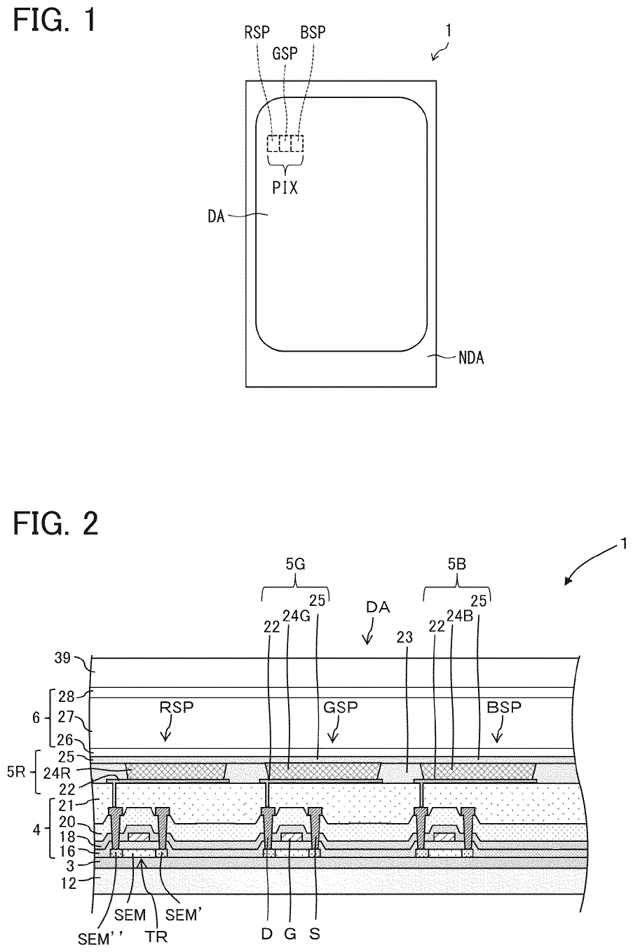

The following describes embodiments of the present disclosure on the basis of FIG. 1 through FIG. 16. Hereinafter, for convenience in description, a component having the same function as that of a component described in a particular embodiment will be denoted by the same sign, and its description will be omitted in some cases.

### First Embodiment

FIG. 1 is a plan view of the schematic configuration of a display device 1 according to a first embodiment.

As illustrated in FIG. 1, the display device 1 has a frame region NDA and a display region DA. The display region DA of the display device 1 is provided with a plurality of pixels PIX. Each pixel PIX includes a red subpixel RSP, a green subpixel GSP, and a blue subpixel BSP. This embodiment describes a non-limiting instance where a single pixel PIX includes the red subpixel RSP, green subpixel GSP, and blue subpixel BSP. For instance, a single pixel PIX may further include a subpixel of another color as well as the red subpixel RSP, green subpixel GSP, and blue subpixel BSP.

FIG. 2 is a cross-sectional view of the schematic configuration of the display region DA of the display device 1 according to the first embodiment.

As illustrated in FIG. 2, in the display region DA of the display device 1 is the following components provided on a substrate 12 in the stated order from the substrate 12: a barrier layer 3; a thin-film transistor layer 4 including transistors TR; red light-emitting elements 5R, green light-emitting elements 5G, blue light-emitting elements 5B, and a bank 23; a sealing layer 6; and a functional film 39.

The red subpixel RSP provided in the display region DA of the display device 1 includes a red light-emitting element 5R (light-emitting element). The green subpixel GSP provided in the display region DA of the display device 1 includes a green light-emitting element 5G (light-emitting element). The blue subpixel BSP provided in the display region DA of the display device 1 includes a blue light-emitting element 5B (light-emitting element). The red light-emitting element 5R included in the red subpixel RSP includes a first electrode 22; a functional layer 24R including a red emission layer, and a second electrode 25. The green light-emitting element 5G included in the green subpixel GSP includes the first electrode 22, a functional layer 24G including a green emission layer, and the second electrode 25. The blue light-emitting element 5B included in the blue subpixel BSP includes the first electrode 22, a functional layer 24B including a blue emission layer, and the second electrode 25.

The substrate 12 may be, for instance, a resin substrate made of a resin material, such as polyimide, or a glass substrate. This embodiment describes, by way of example, an instance where a resin substrate made of a resin material, such as polyimide, is used as the substrate 12 so that the display device 1 is a flexible display device. For the display device 1 to be an inflexible display device, the substrate 12 can be a glass substrate.

The barrier layer 3 is a layer that prevents foreign substances, such as water and oxygen, from entering the transistors TR, red light-emitting elements 5R, green light-emitting elements 5G, and blue light-emitting elements 5B. The barrier layer 3 can be formed from, for instance, a silicon oxide film, a silicon nitride film, or a silicon oxide nitride film, all of which are formed through chemical vapor deposition (CVD), or a laminate of these films.

A transistor-TR portion, which is a portion of the thin-film transistor layer 4 including the transistors TR, includes the following: a semiconductor film SEM, and doped semiconductor films SEM′ and SEM″; an inorganic insulating film 16; a gate electrode G; an inorganic insulating film 18; an inorganic insulating film 20; a source electrode S and a drain electrode D; and a flattening film 21. A portion excluding the transistor-TR portion of the thin-film transistor layer 4 including the transistors TR includes the inorganic insulating film 16, the inorganic insulating film 18, the inorganic insulating film 20, and the flattening film 21.

The semiconductor films SEM, SEM′, and SEM″ may be composed of, for instance, low-temperature polysilicon (LTPS), or an oxide semiconductor (e.g., an In—Ga—Zn—O semiconductor). Although this embodiment describes, by way of example, an instance where the transistors TR have a top-gate structure, the transistors TR may have a bottom-gate structure.

The gate electrode G, the source electrode S, and the drain electrode D can be formed from, for instance, a metal monolayer film or metal laminated film containing at least one of aluminum, tungsten, molybdenum, tantalum, chromium, titanium, and copper.

The inorganic insulating film 16, the inorganic insulating film 18, and the inorganic insulating film 20 can be formed from, for instance, a silicon oxide film, a silicon nitride film, or a silicon oxide nitride film, all of which are formed through CVD, or a laminate of these films.

The flattening film 21 can be made of, for instance, an organic material that can be applied, such as polyimide or acrylic.

The red light-emitting element 5R includes the first electrode 22 positioned over the flattening film 21, the functional layer 24R including the red emission layer, and the second electrode 25. The green light-emitting element 5G includes the first electrode 22 positioned over the flattening film 21, the functional layer 24G including the green emission layer, and the second electrode 25. The blue light-emitting element 5B includes the first electrode 22 positioned over the flattening film 21, the functional layer 24B including the blue emission layer, and the second electrode 25. It is noted that the bank 23, which is insulating and covers the edges of the first electrodes 22, can be formed by, for instance, applying an organic material, such as polyimide or acrylic, followed by patterning it through photolithography.

The sealing layer 6 is a light-transparent film and can be formed from, for example, an inorganic sealing film 26 covering the second electrode 25, an organic film 27 positioned over the inorganic sealing film 26, and an inorganic sealing film 28 positioned over the organic film 27. The sealing layer 6 prevents foreign substances, such as water and oxygen, from permeating the red light-emitting element 5R, the green light-emitting element 5G, and the blue light-emitting element 5B.

The inorganic sealing film 26 and the inorganic sealing film 28 are each an inorganic film and can be formed from, for instance, a silicon oxide film, a silicon nitride film, or a silicon oxide nitride film, all of which are formed through CVD, or a laminate of these films. The organic film 27 is an organic light-transparent film with a flattening effect and can be made of, for instance, an organic material that can be applied, such as acrylic. The organic film 27 may be formed through ink-jet printing for instance. Although this embodiment has described, by way of example, an instance where the sealing layer 6 is formed from two inorganic films and one organic film provided between the two inorganic films, the order of stacking two inorganic films and one organic film is not limited to this instance. Furthermore, the sealing layer 6 may be formed from only an inorganic film or only an organic film; alternatively, the layer may be formed from one inorganic film and two organic films; alternatively, the layer may be formed from two or more inorganic films and two or more organic films.

The functional film 39 is a film having at least one of, for instance, an optical-compensation function, a touch sensor function, and a protection function.

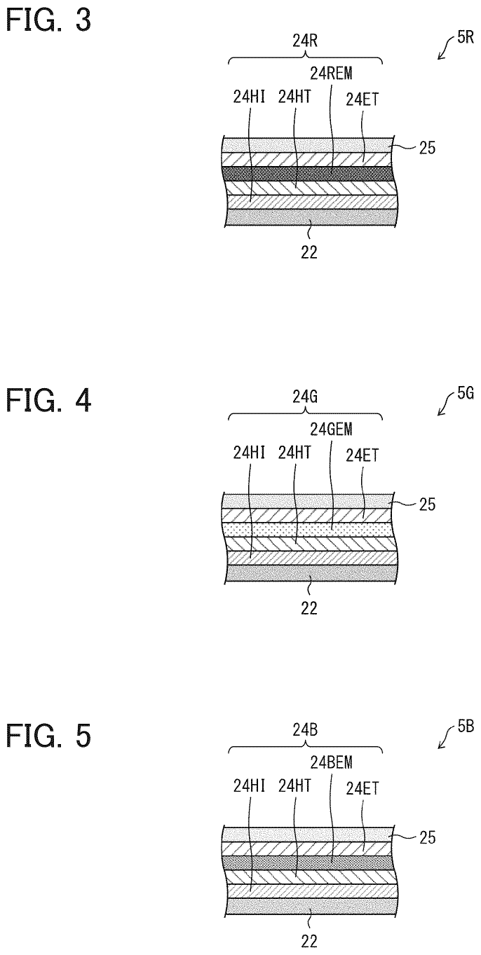

FIG. 3 is a cross-sectional view of the schematic configuration of the red light-emitting element 5R provided in the display device 1 according to the first embodiment. FIG. 4 is a cross-sectional view of the schematic configuration of the green light-emitting element 5G provided in the display device 1 according to the first embodiment. FIG. 5 is a cross-sectional view of the schematic configuration of the blue light-emitting element 5B provided in the display device 1 according to the first embodiment.

As illustrated in FIG. 3, the functional layer 24R provided in the red light-emitting element 5R and including a red emission layer 24REM can be formed by, for instance, stacking a hole injection layer 24HI, a hole transport layer 24HT, the red emission layer 24REM, an electron transport layer 24ET, and an electron injection layer (not shown) sequentially onto the first electrode 22, which is an anode. Each of the hole injection layer, hole transport layer, electron transport layer, and electron injection layer is a charge functional layer within which holes or electrons, both being charges, can move. Of the functional layer 24R including the red emission layer 24REM, one or more of the layers except the red emission layer 24REM may be omitted as appropriate. It is noted that this embodiment describes, by way of example, an instance where the red emission layer 24REM is an emission layer including quantum dots, which are nanoparticles. For instance, the red emission layer 24REM may be an emission layer including quantum dots or an organic emission layer when, of the functional layer 24R including the red emission layer 24REM, at least one of the foregoing charge functional layers except the red emission layer 24REM is a nanoparticle layer including nanoparticles.

The green light-emitting element 5G illustrated in FIG. 4 includes the functional layer 24G including a green emission layer 24GEM. The configuration of the functional layer 24G is similar to that of the functional layer 24R with the exception that the functional layer 24G includes the green emission layer 24GEM.

The blue light-emitting element 5B illustrated in FIG. 5 includes the functional layer 24B including a blue emission layer 24BEM. The configuration of the functional layer 24B is similar to that of the functional layer 24R with the exception that the functional layer 24B includes the blue emission layer 24BEM.

Further, this embodiment describes, by way of example, an instance where the functional layer 24R including the red emission layer 24REM, the functional layer 24G including the green emission layer 24GEM, and the functional layer 24B including the blue emission layer 24BEM each include their hole injection layers 24HI formed in the same process step using the same material, their hole transport layers 24HT formed in the same process step using the same material, their electron transport layers 24ET formed in the same process step using the same material, and their electron injection layers (not shown) formed in the same process step using the same material. For instance, the hole injection layers included in the individual functional layers 24R, 24G, and 24B may be made of mutually different materials; for instance, the hole injection layers included in individual two of the functional layers 24R, 24G, and 24B may be formed in the same process step using the same material, and only the hole injection layer included in the remaining functional layer may be formed in a separate process step using a different material. This holds true for the hole transport layers, electron injection layers, and electron injection layers included in the individual functional layers 24R, 24G, and 24B.

This embodiment describes, by way of example, an instance where each of the red light-emitting element 5R, green light-emitting element 5G, and blue light-emitting element 5B has such a forward stacked structure that the first electrode 22 is an anode, that the second electrode 25 is a cathode, and that the hole injection layer 24HI, the hole transport layer 24HT, any one of the emission layers 24REM, 24GEM, and 24BEM of the respective colors, the electron transport layer 24ET, and the electron injection layer (not shown) are stacked sequentially on the first electrode 22 or anode. For instance, each of the red light-emitting element 5R, green light-emitting element 5G, and blue light-emitting element 5B may have such an inverted stacked structure that the first electrode 22 is a cathode, that the second electrode 25 is an anode, and that the electron injection layer (not shown), the electron transport layer 24ET, any one of the emission layers 24REM, 24GEM, and 24BEM of the respective colors, the hole transport layer 24HT, and the hole injection layer 24HI are stacked sequentially on the first electrode 22 or cathode.

The red light-emitting element 5R, green light-emitting element 5G, and blue light-emitting element 5B illustrated in FIGS. 2 to 5 may be either top-emission light-emitting elements or bottom-emission light-emitting elements. The red light-emitting element 5R, green light-emitting element 5G, and blue light-emitting element 5B according to this embodiment have a forward stacked structure in each which the first electrode 22 or anode, a corresponding one of the functional layers 24R, 24G, and 24B, and the second electrode 25 or cathode is formed in the stated order, and in each of which the second electrode 25 or cathode is thus disposed over the first electrode 22 or anode. As such, for these elements to be top-emission light-emitting elements, the first electrode 22 or anode needs to be made of an electrode material that reflects visible light, and the second electrode 25 or cathode needs to be made of an electrode material that transmits visible light. Further, for these elements to be bottom-emission light-emitting elements, the first electrode 22 or anode needs to be made of an electrode material that transmits visible light, and the second electrode 25 or cathode needs to be made of an electrode material that reflects visible light. It is noted that when the red light-emitting element 5R, green light-emitting element 5G, and blue light-emitting element 5B have an inverted stacked structure, the second electrode 25 or anode is disposed over the first electrode 22 or cathode. As such, for these elements to be top-emission light-emitting elements, the first electrode 22 or cathode needs to be made of an electrode material that reflects visible light, and the second electrode 25 or anode needs to be made of an electrode material that transmits visible light. Further, for these elements to be bottom-emission light-emitting elements, the first electrode 22 or cathode needs to be made of an electrode material that transmits visible light, and the second electrode 25 or anode needs to be made of an electrode material that reflects visible light.

The electrode material that reflects visible light may be any material that can reflect visible light and is conductive; usable examples include, but not limited to, a metal material, such as Al, Mg, Li or Ag, an alloy of the metal material, a stack of the metal material and a transparent metal oxide (e.g., an indium tin oxide, an indium zinc oxide, and an indium gallium zinc oxide), and a stack of the alloy and transparent metal oxide.

On the other hand, the electrode material that transmits visible light may be any material that can transmit visible light and is conductive; examples include, but not limited to, a transparent metal oxide (e.g., an indium tin oxide, an indium zinc oxide, and an indium gallium zinc oxide), a thin film made of a metal material, such as Al, Mg, Li, or Ag, and a nanowire made of a metal material, such as Al or Ag.

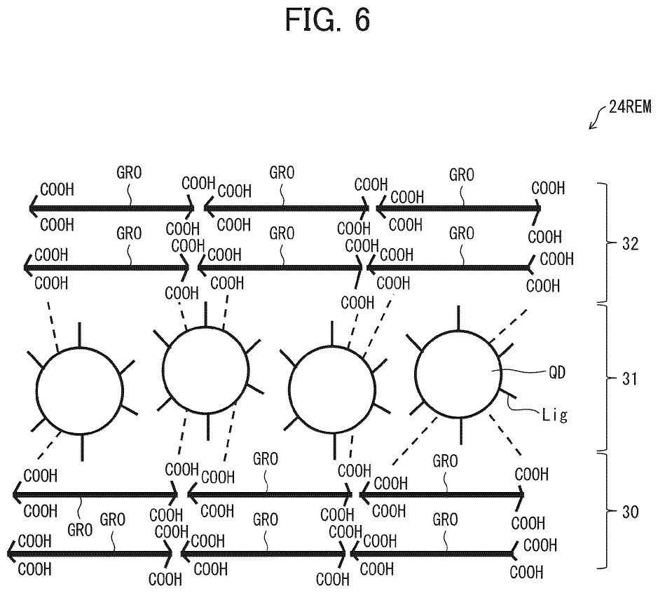

FIG. 6 illustrates an example of the red emission layer 24REM included in the red light-emitting element 5R of the display device 1 according to the first embodiment.

As illustrated in FIG. 6, the red emission layer 24REM includes the following: a nanoparticle layer 31 including nanoparticles, which is a quantum-dot layer including quantum dots QD; and graphene layers 30 and 32 being in contact with the nanoparticle layer 31 and including graphene oxides GRO each having a functional group capable of coordinating with the quantum dot QD or nanoparticle. This embodiment describes, by way of example, an instance where the red emission layer 24REM is provided with the following: the nanoparticle layer 31 including nanoparticles, which is the quantum-dot layer including the quantum dots QD; the graphene layer 30 (first graphene layer) that is disposed under the quantum-dot layer; and the graphene layer 32 (second graphene layer) that is disposed over the quantum-dot layer. For instance, the red emission layer 24REM may be provided with the following: the nanoparticle layer 31 including nanoparticles, which is the quantum-dot layer including the quantum dots QD; and either one of the graphene layer 30 (first graphene layer), which is disposed under the quantum-dot layer, and the graphene layer 32 (second graphene layer), which is disposed over the quantum-dot layer. Furthermore, the red emission layer 24REM may be provided with a plurality of quantum-dot layers, which are the nanoparticle layers 31, and a graphene layer including the graphene oxides GRO, and disposed over and under each of the plurality of quantum-dot layers.

This embodiment describes, by way of example, an instance where a quantum-dot layer that is the nanoparticle layer 31 is formed with a thickness equivalent to a single quantum dot QD, in order to improve patterning accuracy because, as will be described later on, the red emission layer 24REM is formed through patterning. In a quantum-dot layer formed with a thickness equivalent to a single quantum dot QD, the graphene oxides GRO adsorb (denoted by dotted lines in the drawing), like ligands Lig, to part of the surfaces of all the quantum dots QD being in contact with the graphene layer 30 (first graphene layer), which is disposed under the quantum-dot layer; hence, the quantum dots QD formed on the graphene layer 30 including the graphene oxides GRO, that is, the quantum dots QD being in contact with the graphene layer 30 including the graphene oxides GRO loses its dispersibility in a predetermined solvent (e.g., a solvent for dispersing the quantum dots QD). It is noted that there may be a gap between the surfaces of the quantum dots QD and the surface of the graphene layer 30 even when the quantum dots QD and the graphene layer 30 are in contact together. On the other hand, the quantum dots QD not formed on the graphene layer 30 including the graphene oxides GRO, that is, the quantum dots QD not being in contact with the graphene layer including the graphene oxides GRO maintains its dispersibility in the predetermined solvent (e.g., a solvent for dispersing the quantum dots QD). As described above, the greater the difference in the dispersibility of the quantum dots QD in a predetermined solvent (e.g., a solvent for dispersing the quantum dots QD), the further the patterning accuracy can be improved. Further, also in a quantum-dot layer with a thickness equivalent to two quantum dots QD or equivalent to three or more quantum dots QD, the quantum dots QD can achieve a difference in the dispersibility in a predetermined solvent (e.g., a solvent for dispersing the quantum dots QD) to a certain or further extent; accordingly, a quantum-dot layer with a thickness equivalent to two quantum dots QD or equivalent to three or more quantum dots QD can also undergo patterning. Furthermore, forming a stack of, in sequence, a graphene layer including the graphene oxides GRO, a quantum-dot layer formed with a thickness equivalent to a single quantum dot QD, a graphene layer including the graphene oxides GRO, a quantum-dot layer formed with a thickness equivalent to a single quantum dot QD, and a graphene layer including the graphene oxides GRO can increase the thickness of the quantum-dot layers to a thickness equivalent to two quantum dots QD while further improving patterning performance. Further, to increase the thickness of the quantum-dot layers to a thickness equivalent to three or more quantum dots QD, a quantum-dot layer formed with a thickness equivalent to a single quantum dot QD, and a graphene layer including the graphene oxides GRO need to be additionally stacked likewise onto the foregoing stack in the stated order.

The quantum dots QD included in the quantum-dot layer, which is the nanoparticle layer 31, are dots having a maximum width of 100 nm or less. The quantum dots QD each have any shape that satisfies this maximum width; the shape is not limited to a spherical tridimensional shape (circular cross-section shape). For instance, each quantum dot may have a polygonal cross-section shape, a bar-shaped tridimensional shape, a branch-shaped tridimensional shape, a tridimensional shape having surface asperities, or a combination of them.

The quantum dots QD1 preferably contain one or more semiconductor materials selected from the group including Cd, S, Te, Se, Zn, In, N, P, As, Sb, Al, Ga, Pb, Si, Ge, Mg, and their compounds. For instance, the quantum dots QD1 can be formed by the use of a material containing one or more selected from the group consisting of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, CdHgZnTe, CdZnSeS, CdZnSeTe, CdZnSTe, CdHgSeS, CdHgSeTe, CdHgSTe, HgZnSeS, HgZnSeTe, HgZnSTe, GaN, GaP, GaAs, GaSb, AlN, AIP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, SnPbSTe, Si, Ge, SiC, and SiGe.

It is noted that the quantum dot QD that emits red light, a quantum dot that emits green light, and a quantum dot that emits blue light may be quantum dots made of different materials, or quantum dots made of the same material and having different particle diameters. For instance, a quantum dot having the largest particle diameter can be used as the red-emitting quantum dot QD; moreover, a quantum dot having the smallest particle diameter can be used as the blue-emitting quantum dot; moreover, a quantum dot having a particle diameter falling between the particle diameter of the quantum dot used as the red-emitting quantum dot QD and the particle diameter of the quantum dot used as the blue-emitting quantum dot can be used as the green-emitting quantum dot.

The quantum dots QD desirably include, on their surfaces, such ligands Lig as to be able to be dispersed in a solvent for dispersing the quantum dots QD. A non-limiting example is an inorganic ligand. The quantum dots QD also desirably include, on their surfaces, such ligands Lig as to be able to prevent an agglomerate of the quantum dots QD. A non-limiting example is an organic ligand.

Graphene GR is commonly represented by the Structural Formula 1 below. The graphene GR is obtained by exfoliating, through physical exfoliation, ultrasonic exfoliation, centrifugal exfoliation, or other methods, sheets from graphite that is in the form of a stack of multiple sheets of carbon allotropes in which carbon atoms are arranged in a hexagonal honeycomb lattice. It is known that the graphene GR, which has a x-conjugated structure, has high conductivity as well as flexibility and strength, but has low solvent dispersibility. In addition, the graphene GR, which has a gas barrier capability that does not allow gas molecules other than hydrogen to pass therethrough, can prevent oxygen erosion and water erosion. The size of the graphene GR represented by Structural Formula 1 below can be defined by using the maximum width of the graphene GR, which can be determined from an image of the graphene GR obtained with, for example, a scanning electron microscope (SEM), a transmission electron microscope (TEM), or an atomic force microscope (AFM).

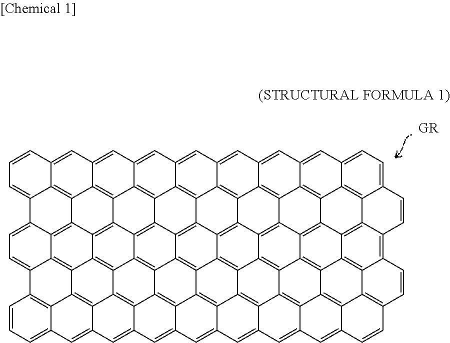 [SMILES: c1cc2cc3cc4cc5cc6cc7cc8cc9ccc%10ccc%11c%12ccc%13ccc%14cc%15cc%16cc%17cc%18cc%19cc%20cc%21cccc%22c%23ccc%24c(c1)c2c1c3c2c4c3c5c4c6c5c7c6c8c7c9c%10c%11c8c9c%12c%13c%14c%10c%15c%11c%16c%12c%17c%13c%18c%14c%19c%15c%20c(c%21%22)c%16c%23c%24c1c1c2c2c3c3c4c4c5c5c6c(c78)c(c%109)c%11c5c%12c4c%13c3c%14c2c%15c%161]

The graphene oxide GRO included in the graphene layers 30 and 32 can be commonly represented by Structural Formula 2 below; the x-conjugated structure of the graphene oxide GRO is partially broken during the sheet exfoliation from the graphite in the forgoing exfoliation step, and functional groups, such as a carboxyl group (COOH group), a hydroxy group (OH group), and an epoxy group, scatter on its surface and at its edge. Since its x-conjugated structure is partially broken, the graphene oxide GRO has a lower conductivity than the aforementioned graphene oxide GR, thereby producing a band gap. However, the graphene oxide GRO has, on the surface and at the edge, functional groups that can be utilized easily and facilitates incorporating modified groups using such functional groups. The size of the graphene oxide GRO represented by Structural Formula 2 below can be defined by using the maximum width of the graphene oxide GRO, which can be determined from an image of the graphene oxide GRO obtained with, for example, a scanning electron microscope (SEM), a transmission electron microscope (TEM), or an atomic force microscope (AFM). It is noted that the size of the graphene oxide GRO, that is, the maximum width thereof preferably ranges from 100 nm inclusive to 10 μm inclusive, more desirably from 300 nm inclusive to 5 μm inclusive, in view of achieving high solvent resistance and high gas barrier capability, achieving the solvent dispersibility of the graphene oxide GRO, and achieving patterning accuracy without increasing the thicknesses of the graphene layers 30 and 32. For example, the maximum width of 10% or less graphene oxides GRO as small in number as the total number of graphene oxides GRO included in the graphene layer 30 falls outside the foregoing preferred range (i.e., 100 nm to 10 μm, or 300 nm to 5 μm) in some cases. In such cases, the foregoing effects can be achieved when the remaining graphene oxides GRO included in the graphene layer 30 except the graphene oxides GRO whose maximum width falls outside the foregoing preferred range have a maximum width falling within the foregoing preferred range (i.e., 100 nm to 10 μm, or 300 nm to 5 μm). This holds true for the graphene oxides GRO included in the graphene layer 32.

It is noted that the sheets of the graphene oxide GRO can be exfoliated through physical exfoliation, ultrasonic exfoliation, centrifugal exfoliation, or other methods. The graphene oxide GRO obtained through ultrasonic exfoliation tends to offer a flat surface (sheet) with the foregoing maximum width being small; further, the graphene oxide GRO obtained through centrifugal exfoliation offers a plurality of flat surfaces (sheets) ranging gradually from a flat surface (sheet) with the foregoing maximum width being large to a flat surface (sheet) with the foregoing maximum width being small.

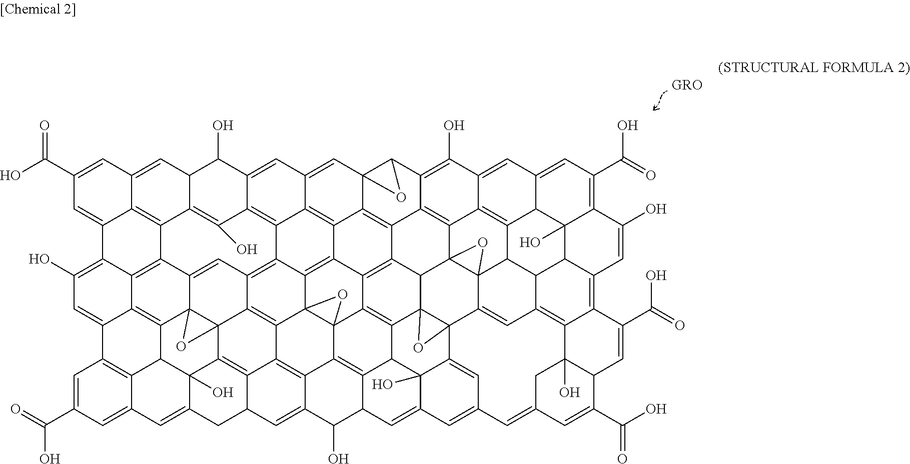

As illustrated in FIG. 6, the red emission layer 24REM provided in the red light-emitting element 5R includes the following: the nanoparticle layer 31, which is a quantum-dot layer; and the graphene layers 30 and 32 being in contact with the nanoparticle layer 31 or quantum-dot layer, and including the graphene oxides GRO each having a functional group capable of coordinating with the quantum dot QD or nanoparticle. Although this embodiment describes, by way of example, an instance where the graphene oxide GRO included in the graphene layers 30 and 32 includes a carboxyl group (COOH group) as a functional group capable of coordinating with the quantum dot QD or nanoparticle, and where-COO″ of the carboxyl group (COOH group) coordinates with the surface of the quantum dot QD, any functional group capable of coordinating with the quantum dot QD or nanoparticle may be used. It is noted that although FIG. 6 illustrates, by way of example, an instance where one or two quantum dots QD coordinate with each single graphene oxide GRO, three or more quantum dots QD may coordinate with each single graphene oxide GRO. The graphene layers 30 and 32 including such graphene oxides GRO can achieve high solvent resistance and high gas barrier capability and can achieve the red light-emitting element 5 and display device 1 in which the nanoparticle layer 31 or quantum-dot layer can undergo patterning. The graphene oxide GRO included in the graphene layers 30 and 32 preferably further includes one or more of a thiol (—SH) group, an amino (—NR₂) group, and a phosphonic (—P(═O)(OR)₂) group in addition to a carboxyl group (COOH group) as functional groups capable of coordinating with the quantum dots QD or nanoparticles. These R groups each independently represent a hydrogen atom, or any organic group, such as an alkyl group and an aryl group. Such a configuration can achieve higher solvent resistance and higher gas barrier capability and can achieve the red light-emitting element 5R and display device 1 in which the nanoparticle layer 31 or quantum-dot layer can undergo patterning with higher accuracy.

Reference is made to an observation performed on the graphene layers 30 and 32 in FIG. 6, and the nanoparticle layer 31 or quantum-dot layer in FIG. 6 being in contact with the graphene layers 30 and 32. When, for instance, there is a carboxyl group, which is a functional group capable of coordinating with the quantum dot QD or nanoparticle, found in the observed region, it may be considered that —COO— of the carboxyl group (COOH group) coordinates with the surface of the quantum dot QD.

It is noted that the graphene layers 30 and 32 including the graphene oxides GRO illustrated in FIG. 6 are preferably formed with a thickness of about 0.3 nm, which is a thickness equivalent to a single graphene oxide GRO, in view of hole-and-electron injection performance into the nanoparticle layer 31 or quantum-dot layer. It is also noted that the graphene layers 30 and 32 including the graphene oxides GRO are preferably formed with a thickness of 100 nm or less in view of the fact that the graphene oxide GRO has lower conductivity than the graphene GR. As such, the graphene layers 30 and 32 including the graphene oxides GRO preferably have a thickness of 0.3 to 100 nm inclusive, more desirably, 0.3 to 5 nm inclusive.

This embodiment has described, by way of example, an instance where the graphene layers 30 and 32 are formed by the use of the graphene oxide GRO, as described above. The graphene layers 30 and 32 may be formed by the use of a reduced graphene oxide PGRO or a modified graphene oxide MGRO, both of which will be described later on, instead of the graphene oxide GRO. Furthermore, the graphene layers 30 and 32 may be formed by the use of two or more of the graphene oxide GRO, reduced graphene oxide PGRO, and modified graphene oxide MGRO. Further, although this embodiment has described, by way of example, an instance where the graphene layer 30 and the graphene layer 32 are formed by the use of the same material, the graphene layer 30 and the graphene layer 32 may be formed by the use of different materials.

The reduced graphene oxide PGRO, which can be used for forming the graphene layers 30 and 32, can be commonly represented by Structural Formula 3 below. The reduced graphene oxide PGRO is obtained by reducing the above-mentioned graphene oxide GRO, thus removing some of the above-mentioned functional groups to bring the reduced graphene oxide GRO close to the above-mentioned graphene GR. The reduced graphene oxide PGRO has improved conductivity when compared to the graphene oxide GRO. Further, the reduced graphene oxide PGRO, which has a small number of functional groups, can relatively easily incorporate a modified group by the use of the functional groups, but has a smaller number of functional groups capable of coordinating with the quantum dots QD or nanoparticles than the graphene oxide GRO.

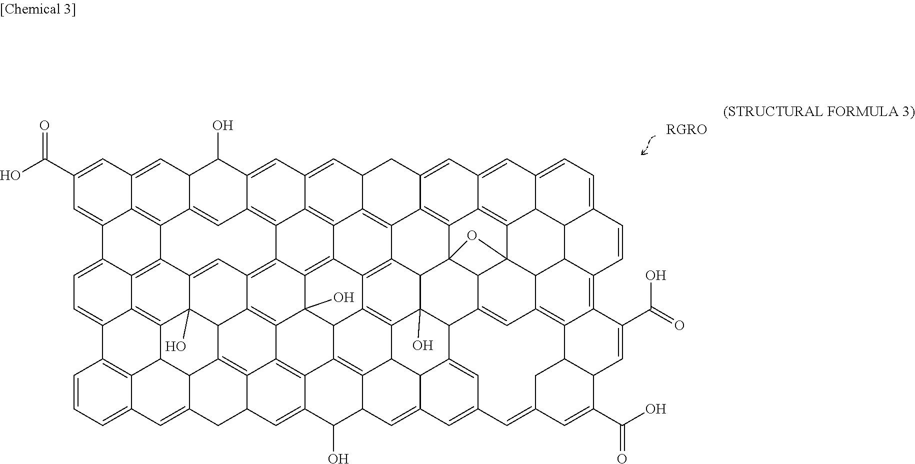

The modified graphene oxide MGRO, which can be used for forming the graphene layers 30 and 32, can be commonly represented by Structural Formula 4 below. The modified graphene oxide MGRO is, for instance, a graphene oxide incorporating a —NH₂ group, which is an amino (—NR₂) group, by the use of some of hydroxy groups (OH groups) scattering on the surface and at the edge of the graphene oxide GRO. The modified graphene oxide MGRO, which has a —NH₂ group or amino (—NR₂) group in addition to a carboxyl group (COOH group) as functional groups capable of coordinating with the quantum dots QD or nanoparticles, can achieve higher solvent resistance and higher gas barrier capability and can achieve the red light-emitting element 5R and display device 1 in which the nanoparticle layer 31 or quantum-dot layer can undergo patterning with higher accuracy.

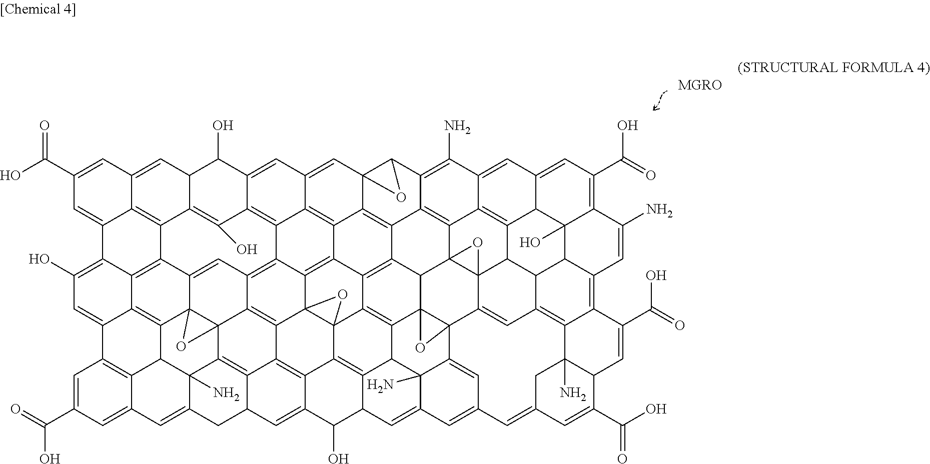

It is noted that although this embodiment has described, by way of example, an amine-modified graphene oxide incorporating, as described above, a —NH₂ group, which is an amino (—NR₂) group, by the use of some of hydroxy groups (OH groups), a thiol (—SH) group, a phosphonic (—P(═O)(OR)₂) group, or other kinds of group, all of which are functional groups capable of coordinating with the quantum dots QD or nanoparticles, may be incorporated by the use of other functional groups, such as an epoxy group, scattering on the surface and at the edge of the graphene oxide GRO.

The size of the reduced graphene oxide PGRO or modified graphene oxide MGRO can be defined by using the maximum width of the reduced graphene oxide PGRO or modified graphene oxide MGRO, which can be determined from an image of the reduced graphene oxide PGRO or modified graphene oxide MGRO obtained with, for example, a scanning electron microscope (SEM), a transmission electron microscope (TEM), or an atomic force microscope (AFM). It is noted that the size of the reduced graphene oxide PGRO or modified graphene oxide MGRO, that is, the maximum width thereof preferably ranges from 100 nm inclusive to 10 μm inclusive, more desirably from 300 nm inclusive to 5 μm inclusive, in view of achieving high solvent resistance and high gas barrier capability and achieving the solvent dispersibility of the reduced graphene oxide PGRO or modified graphene oxide MGRO without increasing the thicknesses of the graphene layers 30 and 32. For example, in the graphene layer 30, 10% or less reduced graphene oxides PGRO or modified graphene oxides MGRO as small in number as the total number of reduced graphene oxides PGRO or modified graphene oxides MGRO included in the graphene layer 30 have a maximum width falling outside the foregoing preferred range (i.e., 100 nm to 10 μm, or 300 nm to 5 μm) in some cases. In such cases, the foregoing effects can be achieved when the remaining reduced graphene oxides PGRO or modified graphene oxide MGRO included in the graphene layer 30 except the reduced graphene oxides PGRO or modified graphene oxides MGRO whose maximum width falls outside the foregoing preferred range have a maximum width falling within the foregoing preferred range (i.e., 100 nm to 10 μm, or 300 nm to 5 μm). This holds true for the reduced graphene oxides PGRO or modified graphene oxides MGRO included in the graphene layer 32.

It is noted that the graphene layers 30 and 32 including the reduced graphene oxides PGRO or modified graphene oxides MGRO are preferably formed with a thickness of about 0.3 nm, which is a thickness equivalent to a single reduced graphene oxide PGRO or a single modified graphene oxide MGRO, in view of hole-and-electron injection performance into the nanoparticle layer 31 or quantum-dot layer. It is also noted that the graphene layers 30 and 32 including the reduced graphene oxides PGRO or modified graphene oxides MGRO are preferably formed with a thickness of 100 nm or less in view of the fact that the reduced graphene oxide PGRO or modified graphene oxide MGRO has lower conductivity than the graphene GR. As such, the graphene layers 30 and 32 including the reduced graphene oxides PGRO or modified graphene oxides MGRO preferably have a thickness of 0.3 to 100 nm inclusive, more desirably, 0.3 to 5 nm inclusive.

This embodiment has described, by way of example, an instance where, as illustrated in FIG. 6, the red emission layer 24REM provided in the red light-emitting element 5R illustrated in FIG. 3 includes the following: the nanoparticle layer 31 that is a red light-emitting quantum-dot layer; and the graphene layers 30 and 32 being in contact with the nanoparticle layer 31 or red light-emitting quantum-dot layer, and including the graphene oxides GRO each having a functional group capable of coordinating with a red light-emitting quantum dot QD, which is a nanoparticle. Although not shown, the green emission layer 24GEM provided in the green light-emitting quantum dot 5G illustrated in FIG. 4 may include the following: the nanoparticle layer 31 that is a green light-emitting quantum-dot layer; and the graphene layers 30 and 32 being in contact with the nanoparticle layer 31 or green light-emitting quantum-dot layer, and including the graphene oxides GRO each having a functional group capable of coordinating with a green light-emitting quantum dot QD, which is a nanoparticle. In addition, although not shown, the blue emission layer 24BEM provided in the blue light-emitting quantum dot 5B illustrated in FIG. 5 may include the following: the nanoparticle layer 31 that is a blue light-emitting quantum-dot layer; and the graphene layers 30 and 32 being in contact with the nanoparticle layer 31 or blue light-emitting quantum-dot layer, and including the graphene oxides GRO each having a functional group capable of coordinating with a blue light-emitting quantum dot QD, which is a nanoparticle.

The hole injection layer 24HI illustrated in FIGS. 3, 4 and 5 may be made of any hole-injecting material that can stabilize hole injection into these quantum-dot layers. PEDOT: PSS, which is a nanoparticle-free material, is used in this embodiment by way of example only.

The hole transport layer 24HT illustrated in FIGS. 3, 4 and 5 may be made of any hole-transporting material that can transport holes injected from the first electrode 22 or anode to these quantum-dot layers. TFB, which is a nanoparticle-free material, is used in this embodiment by way of example only.

The electron transport layer 24ET illustrated in FIGS. 3, 4 and 5 may be made of any electron-transporting material that can transport electrons injected from the second electrode 25 or cathode to these quantum-dot layers. TPBi, which is a nanoparticle-free material, is used in this embodiment by way of example only.

The electron injection material, not shown, may be made of any electron-injecting material that can stabilize electron injection into these quantum-dot layers. Lithium fluoride (LiF), which is a nanoparticle-free material, is used in this embodiment by way of example only.

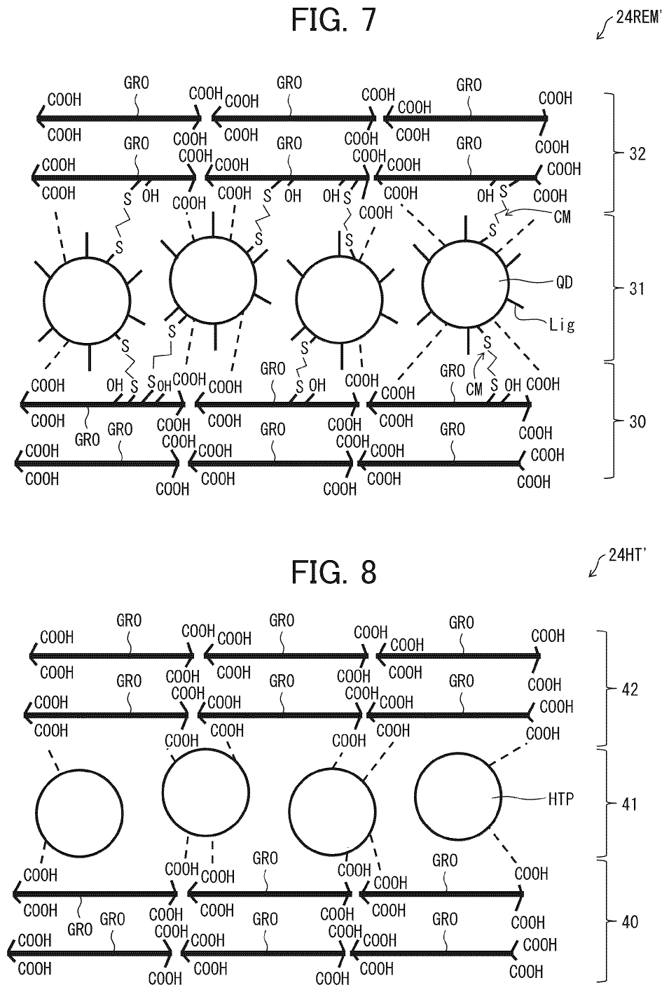

FIG. 7 illustrates another example of a red emission layer 24REM′ that can be included in the red light-emitting element 5R of the display device 1 according to the first embodiment.

The red emission layer 24REM′ illustrated in FIG. 7 is different from the red emission layer 24REM illustrated in FIG. 6 in that the red emission layer 24REM′ includes crosslink molecules CM (cross-linking agent).

Each crosslink molecule CM (cross-linking agent) has one end including an acid functional group, and the other end including one or more of a carboxyl group, a thiol group, an amino group, and a phosphonic group. The graphene oxide GRO and the quantum dot QD, which is a nanoparticle, are joined together via the crosslink molecule CM. The acid functional group is preferably any one of an alcohol group, a phenol group, a thiol group, an amine group, a nitrile group, and a carboxyl group. Further, the crosslink molecule CM preferably includes three or more thiol groups.

This embodiment describes, by way of example, an instance where 1,2-ethanedithiol is used in which each crosslink molecule CM (cross-linking agent) has a thiol group as an acid functional group that reacts with the epoxy group of the graphene oxide GRO, and another thiol group as a functional group that coordinates with the surface of the quantum dot QD. At least one of heating and UV light (UV) irradiation causes the epoxy group of the graphene oxide GRO to react with one of the thiol groups of 1,2-ethanedithiol (see Reaction Formula 1 below) and causes the other thiol group of 1,2-ethanedithiol to react (coordinate) with the surface of the quantum dot QD (see FIG. 7), so that the graphene oxide GRO and the quantum dot QD, which is a nanoparticle, are joined together via the crosslink molecule CM.

Reference is made to an observation performed on the graphene layers 30 and 32 in FIG. 7, and the nanoparticle layer 31 or quantum-dot layer in FIG. 7 being in contact with the graphene layers 30 and 32. When there is a crosslink molecule CM found in the observed region, it may be considered that the graphene oxide GRO and the quantum dot QD, which is a nanoparticle, are joined together via the crosslink molecule CM.

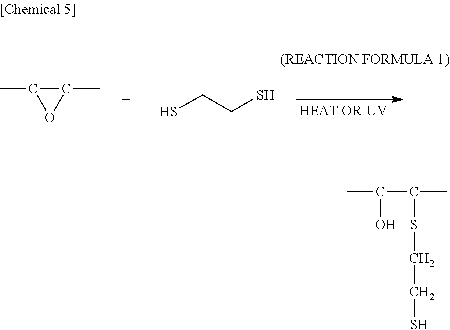

The crosslink molecule CM (cross-linking agent) including two thiol groups is not limited to foregoing 1,2-ethanedithiol. Non-limiting examples of the crosslink molecule CM (cross-linking agent) including three or more thiol groups include trimethylolpropane tris(3-mercaptopropionate), which is a crosslink molecule including three thiol groups represented by Chemical Formula 1 below, pentaerythritol tetra(3-mercaptopropionate), which is a crosslinking molecule CM including four thiol groups represented by Chemical Formula 2 below, and dipentaerythritol hexakis (3-mercaptopropionate), which is a crosslink molecule CM including six thiol groups represented by Chemical Formula 3 below.

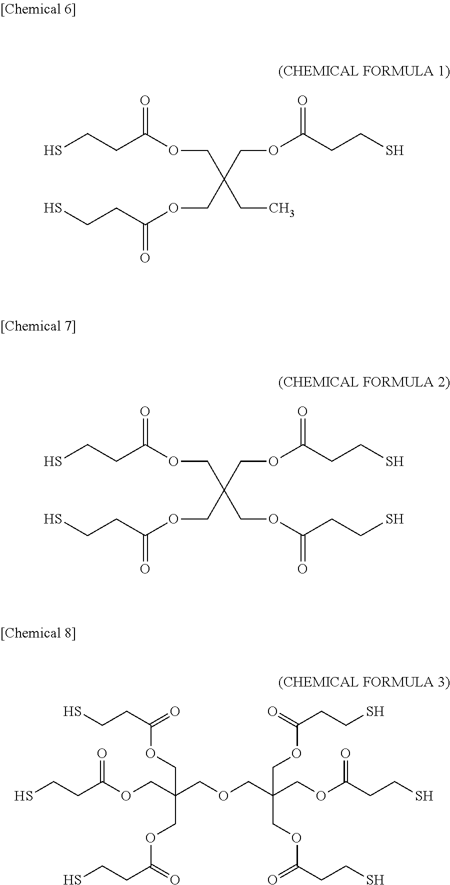 [SMILES: CCC(COC(=O)CCS)(COC(=O)CCS)COC(=O)CCS ; O=C(CCS)OCC(COC(=O)CCS)(COC(=O)CCS)COC(=O)CCS ; O=C(CCS)OCC(COCC(COC(=O)CCS)(COC(=O)CCS)COC(=O)CCS)(COC(=O)CCS)COC(=O)CCS]

As such, since the graphene oxide GRO and the quantum dot QD, which is a nanoparticle, are joined together via the crosslink molecule CM, using the foregoing crosslink molecule CM (cross-linking agent) can achieve higher solvent resistance and higher gas barrier capability and can achieve the red light-emitting element 5R and display device 1 in which the nanoparticle layer 31 or quantum-dot layer can undergo patterning with higher accuracy.

It is noted that although this embodiment has described, by way of example, an instance where the graphene oxide GRO and the quantum dot QD, which is a nanoparticle, are joined together via the crosslink molecule CM, the reduced graphene oxide PGRO having an epoxy group or the modified graphene oxide MGRO having an epoxy group may be joined to the quantum dot QD, which is a nanoparticle, via the crosslink molecule CM.

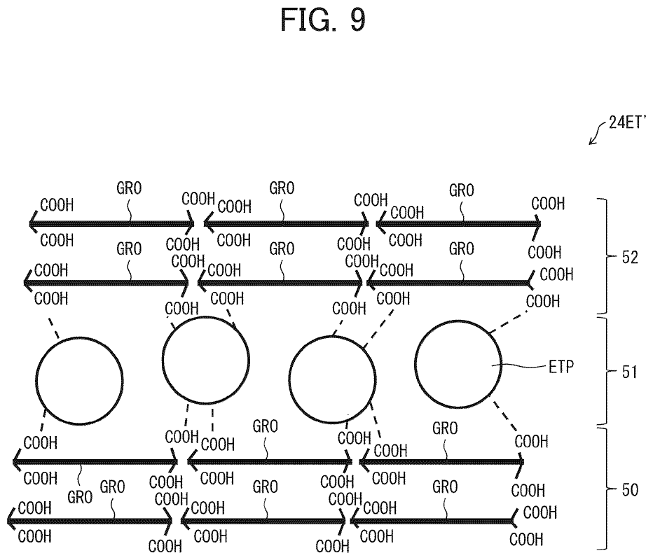

This embodiment has described, by way of example, an instance where, as described above, the emission layer of the functional layer includes the quantum dots QD, which are nanoparticles, and the other layers but the emission layer of the functional layer are made of nanoparticle-free materials. For instance, as will be described based on FIGS. 8 and 9, the emission layer of the functional layer may include the quantum dots QD or nanoparticles, and at least one of the layers but the emission layer of the functional layer may be made of a nanoparticle-containing material; alternatively, the emission layer of the functional layer may be an organic emission layer, and at least one of the layers but the emission layer of the functional layer may be made of a nanoparticle-containing material.

FIG. 8 illustrates an example of a hole transport layer 24HT′ that can be included in the red light-emitting element 5R of the display device 1 according to the first embodiment.

The hole transport layer 24HT′ is different from the hole transport layer 24HT, which is a nanoparticle-free material, in that the hole transport layer 24HT′ includes hole-transporting nanoparticles HTP, which are charge functional nanoparticles. A non-limiting example of the hole-transporting nanoparticles HTP is metal oxide nanoparticles containing at least one of Ni, Mg, Mo, Cu, Co, Cr, and Ti.

As illustrated in FIG. 8, the hole transport layer 24HT′ includes the following: a nanoparticle layer 41 including the hole-transporting nanoparticles HTP; and graphene layers 40 and 42 being in contact with the nanoparticle layer 41 and including the graphene oxides GRO each having a functional group capable of coordinating with the hole-transporting nanoparticle HTP. This embodiment describes, by way of example, an instance where the hole transport layer 24HT′ is provided with the following: the nanoparticle layer 41 including the hole-transporting nanoparticles HTP; the graphene layer (first graphene layer) 40, which is disposed under the nanoparticle layer 41; and the graphene layer (second graphene layer) 42, which is disposed over the nanoparticle layer 41. For instance, the hole transport layer 24HT′ may be provided with the nanoparticle layer 41, and either one of the graphene layer (first graphene layer) 40, which is disposed under the nanoparticle layer 41, and the graphene layer (second graphene layer) 42, which is disposed over the nanoparticle layer 41. Furthermore, the hole transport layer 24HT′ may be provided with a plurality of nanoparticle layers 41, and graphene layers including the graphene oxides GRO and disposed over and under each of the plurality of nanoparticle layers 41.

Although not shown, the hole injection layer may have the same configuration as the hole transport layer 24 HT′.

Further, combining the foregoing red emission layer 24REM and hole transport layer 24HT′ together can achieve higher solvent resistance and higher gas barrier capability and can achieve the red light-emitting element 5R and display device 1 in which the nanoparticle layer 31 or quantum-dot layer and the nanoparticle layer 41 can undergo patterning with higher accuracy. It is noted that the foregoing crosslinking molecules CM (crosslinking agent) can also be used for the hole transport layer 24HT′.

FIG. 9 illustrates an example of an electron transport layer 24ET′ that can be included in the red light-emitting element 5R of the display device 1 according to the first embodiment.

The electron transport layer 24ET′ is different from the electron transport layer 24ET, which is a nanoparticle-free material, in that the electron transport layer 24ET′ includes electron-transporting nanoparticles ETP. A non-limiting example of the electron-transporting nanoparticles ETP is metal oxide nanoparticles containing at least one of Zn, Mg, Ti, Si, Sn, W, Ta, Ba, Zr, Al, Y, and Hf.

The electron transport layer 24ET′ illustrated in FIG. 9 is different from the hole transport layer 24HT′ illustrated in FIG. 8 in that the electron transport layer 24ET′ is provided with a nanoparticle layer 51 including the electron-transporting nanoparticles ETP, which are charge functional nanoparticles, instead of the nanoparticle layer 41 including the hole-transporting nanoparticles HTP, which are charge functional nanoparticles, whereas graphene layers 50 and 52 including the graphene oxides GRO each having a functional group capable of coordinating with the electron-transporting nanoparticle ETP are the same as the graphene layers 40 and 42. The electron transport layer 24ET′ illustrated in FIG. 9 can offer an effect similar to that offered by the hole transport layer 24HT′ illustrated in FIG. 8.

Although not shown, the electron injection layer may have a configuration similar to that of the electron transport layer 24ET′.

Further, combining the foregoing red emission layer 24REM, hole transport layer 24HT′, and electron transport layer 24ET′ together can achieve higher solvent resistance and higher gas barrier capability and can achieve the red light-emitting element 5R and display device 1 in which the nanoparticle layer 31 or quantum-dot layer, the nanoparticle layer 41, and the nanoparticle layer 51 can undergo patterning with higher accuracy.

It is noted that the foregoing crosslinking molecules CM (crosslinking agent) can also be used for the electron transport layer 24ET′.

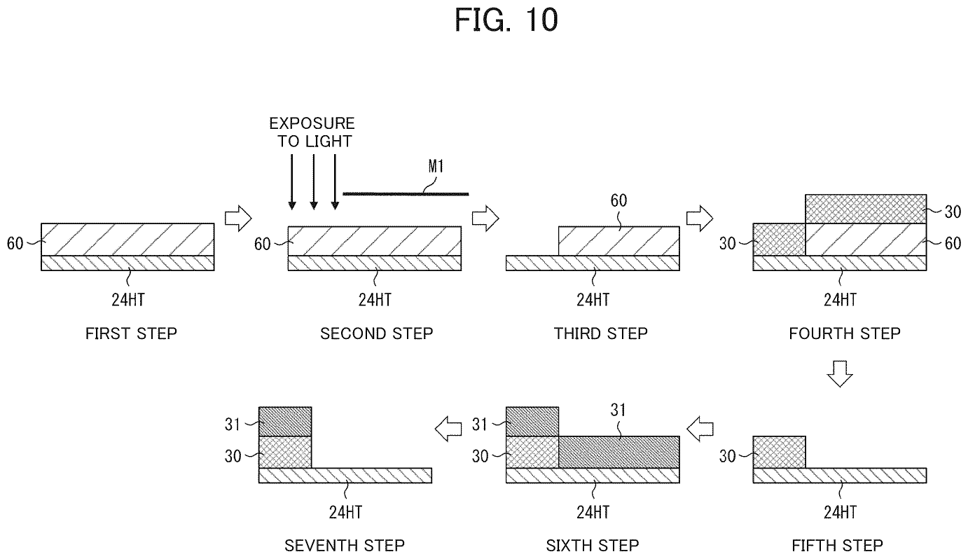

First through seventh steps illustrated in FIG. 10 constitute part of a step of forming the red emission layer 24REM included in the red light-emitting element 5R of the display device 1 according to the first embodiment illustrated in FIG. 6.

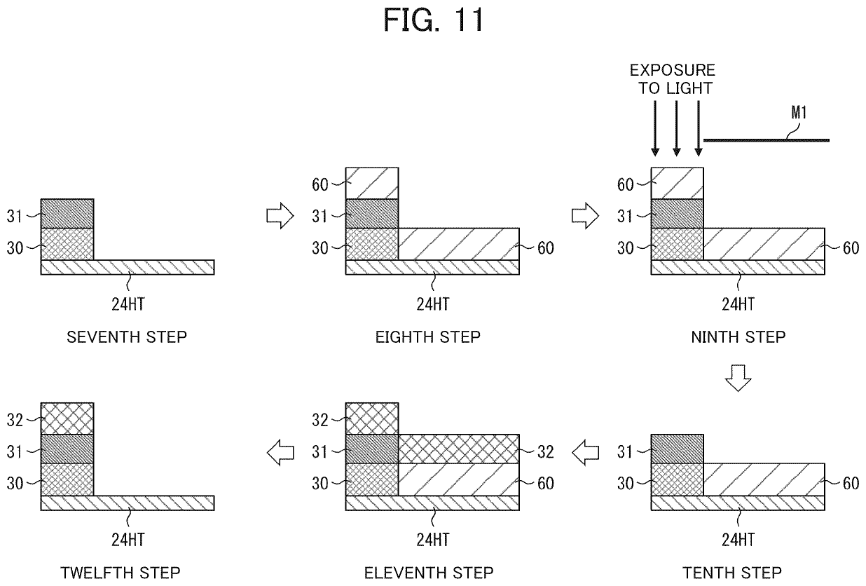

The seventh step through a twelfth step illustrated in FIG. 11 constitute the remaining part of the step of forming the red emission layer 24REM included in the red light-emitting element 5R of the display device 1 according to the first embodiment illustrated in FIG. 6.

The first through fifth steps illustrated in FIG. 10 constitute a step of forming the graphene layer (first graphene layer) 30 that is performed after a nanoparticle-layer formation step, which is the sixth step in FIG. 10. In the step of forming the graphene layer (first graphene layer) 30, the graphene layer (first graphene layer) 30 undergoes patterning into a predetermined shape through liftoff using a resist 60.

First, in the first step illustrated in FIG. 10, i.e., forming the resist 60, the resist 60 is formed onto the entire surface of the hole transport layer 24HT.

Then, in the second step illustrated in FIG. 10, i.e., subjecting the resist 60 to exposure, the resist 60 provided on the hole transport layer 24HT undergoes exposure in a predetermined region by the use of a mask M1 with an opening through which the predetermined region is irradiated with exposure light.

Then, in the third step illustrated in FIG. 10, i.e., subjecting the resist 60 to development, the resist 60 undergoes development by the use of an alkali developing solution to remove the exposed predetermined region, thereby forming an opening in the predetermined region of the resist 60. Although the resist 60 is a positive resist in this embodiment in view of the exfoliation characteristic of the resist 60 in the fifth step illustrated in FIG. 10, i.e., exfoliating the resist 60, which will be described later on, the resist 60 may be a negative resist.

Then, as illustrated in the fourth step in FIG. 10, the graphene layer (first graphene layer) 30 is formed onto the resist 60 and hole transport layer 24HT by the use of a graphene oxide solution containing a graphene oxide having a functional group capable of coordinating with the nanoparticle QD included in the nanoparticle layer 31, and a second solvent (e.g., isopropyl alcohol or IPA for short) capable of dispersing the graphene oxide.

Then, in the fifth step illustrated in FIG. 10, i.e., exfoliating the resist 60, the resist 60 is exfoliated with a remover liquid, an example of which is PGMEA, so that the resist 60 and the graphene layer (first graphene layer) 30 formed on the resist 60 can be separated from each other.

Although this embodiment has described, by way of example, an instance where, as described above, the graphene layer (first graphene layer) 30 undergoes patterning into a predetermined shape through liftoff using the resist 60, the graphene layer (first graphene layer) 30 may undergo patterning into the predetermined shape through another method other than liftoff.

Then, in the sixth step illustrated in FIG. 10, i.e., a nanoparticle-layer formation step, the nanoparticle layer 31 is formed onto the entire surface by using a nanoparticle solution containing the quantum dot QD or nanoparticle, and a first solvent (e.g., octane) capable of dispersing the quantum dot QD. That is, in the sixth step in FIG. 10, i.e., the nanoparticle-layer formation step, the nanoparticle layer 31 is formed so as to be in contact with the graphene layer (first graphene layer) 30 partly.

Then, in the seventh step illustrated in FIG. 10, i.e., patterning the nanoparticle layer 31, only the nanoparticle layer 31 being in contact with the graphene layer (first graphene layer) 30 patterned into the predetermined shape is caused to remain by etching using the first solvent (e.g., octane), so that the nanoparticle layer 31 not being in contact with the graphene layer (first graphene layer) 30 can be removed. The reason why the nanoparticle layer 31 can undergo patterning through etching with the first solvent (e.g., octane) in this way is that the quantum dots QD included in the nanoparticle layer 31 being in contact with the graphene layer (first graphene layer) 30 including the graphene oxides GRO lose their dispersibility in the first solvent (e.g., octane), and that the quantum dots QD included in the nanoparticle layer 31 not formed on the graphene layer (first graphene layer) 30 including the graphene oxides GRO, that is, the quantum dots QD included in the nanoparticle layer 31 not being in contact with the graphene layer (first graphene layer) 30 including the graphene oxides GRO maintain their dispersibility in the first solvent (e.g., octane).

Moreover, the eighth through twelfth steps illustrated in FIG. 11 constitute a step of forming the graphene layer (second graphene layer) 32 that is performed after the step of patterning the nanoparticle layer 31, which is the seventh step in FIGS. 10 and 11. In the step of forming the graphene layer (second graphene layer) 32, the graphene layer (second graphene layer) 32 undergoes patterning into a predetermined shape through liftoff using the resist 60.

First, in the eighth step illustrated in FIG. 11, i.e., forming the resist 60, the resist 60 is formed onto the entire surfaces of the hole transport layer 24HT and nanoparticle layer 31.

Then, in the ninth step illustrated in FIG. 11, i.e., subjecting the resist 60 to exposure, the resist 60 provided on the nanoparticle layer 31 undergoes exposure by the use of the mask M1.

Then, in the tenth step illustrated in FIG. 11, i.e., subjecting the resist 60 to development, the resist 60 provided on the nanoparticle layer 31 is removed through development by the use of an alkali developing solution.

Then, as illustrated in the eleventh step in FIG. 11, the graphene layer (second graphene layer) 32 is formed onto the entire surfaces of the resist 60 and nanoparticle layer 31 by the use of a graphene oxide solution containing a graphene oxide having a functional group capable of coordinating with the nanoparticle QD included in the nanoparticle layer 31, and a second solvent (e.g., isopropyl alcohol or IPA for short) capable of dispersing the graphene oxide. It is noted that in this step, the graphene layer (second graphene layer) 32 is formed so as to be in contact with the nanoparticle layer 31 partly.

Then, in the twelfth step illustrated in FIG. 11, i.e., exfoliating the resist 60, the resist 60 is exfoliated with a remover liquid, an example of which is PGMEA, so that the resist 60 and the graphene layer (second graphene layer) 32 formed on the resist 60 can be separated from each other.

Through the foregoing process steps, the red emission layer 24REM provided with the quantum-dot layer including the quantum dots QD, which is the nanoparticle layer 31 including nanoparticles, the graphene layer (first graphene layer) 30, which is disposed under the quantum-dot layer, and the graphene layer (second graphene layer) 32, which is disposed over the quantum-dot layer, can be formed in a predetermined region on the hole transport layer 24HT, as illustrated in the twelfth step in FIG. 11.

Although this embodiment has described, by way of example, an instance where, as described above, the graphene layer (second graphene layer) 32 undergoes patterning into a predetermined shape through liftoff using the resist 60, the graphene layer (second graphene layer) 32 may undergo patterning into the predetermined shape through another method other than liftoff.

Although the foregoing production process step (production method) is applied to, by way of example, the nanoparticle layer 31 including the quantum dots QD, these production process step is applicable to the nanoparticle layer 41 including the hole-transporting nanoparticles HTP, or the nanoparticle layer 51 including the electron-transporting nanoparticles ETP, as a matter of course.

It is noted that although the foregoing has described, by way of example, an instance where the production process step (production method) includes both of the step of forming the graphene layer (first graphene layer) 30 and the step of forming the graphene layer (second graphene layer) 32, the production process step (production method) needs to include at least one of the step of forming the graphene layer (first graphene layer) 30 and the step of forming the graphene layer (second graphene layer) 32.

Further, the production process step (production method) preferably further includes a cross-linking-agent processing step of performing processing by using the foregoing cross-linking agent (crosslink molecules CM). The cross-linking-agent processing step can be performed on at least one of a stack of the graphene layer (first graphene layer) 30 and the nanoparticle layer 31, and a stack of the nanoparticle layer 31 and the graphene layer (second graphene layer) 32.

Further, the production process step (production method) preferably further includes a step of curing the cross-linking agent (crosslink molecules CM) that is performed after the cross-linking-agent processing step. At least one of light irradiation and heating can be performed in this curing step.

Further, the production process step (production method) preferably further includes a rinse step that is performed after the curing step. An excess of the cross-linking agent (crosslink molecules CM) can be removed in the rinse step.

Further, although the foregoing has described, by way of example, an instance where the production process step (production method) includes forming the graphene layer (first graphene layer) 30 and the graphene layer (second graphene layer) 32 by using the graphene oxide GRO, these graphene layers may be formed by the use of the reduced graphene oxide PGRO or the modified graphene oxide MGRO instead of the graphene oxide GRO. Furthermore, the graphene layer (first graphene layer) 30 and the graphene layer (second graphene layer) 32 may be formed by the use of two or more of the graphene oxide GRO, reduced graphene oxide PGRO, and modified graphene oxide MGRO.

### Second Embodiment

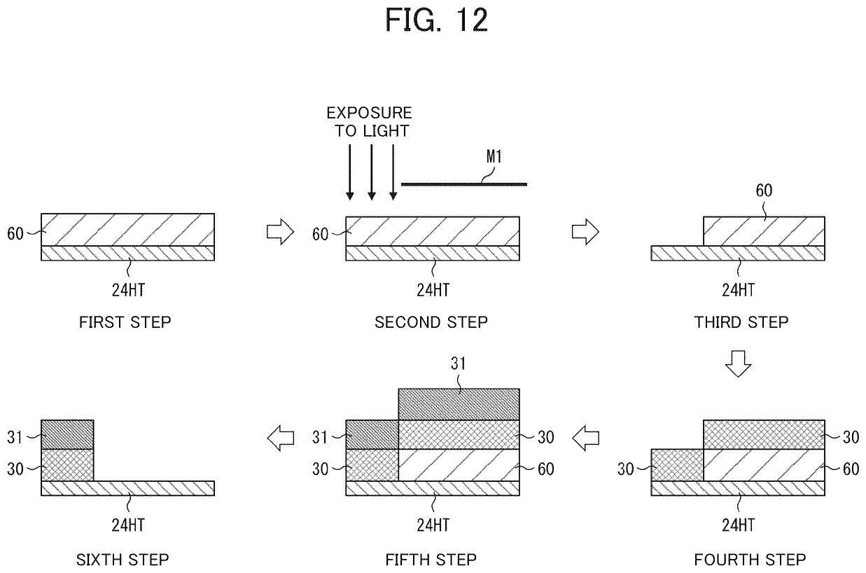

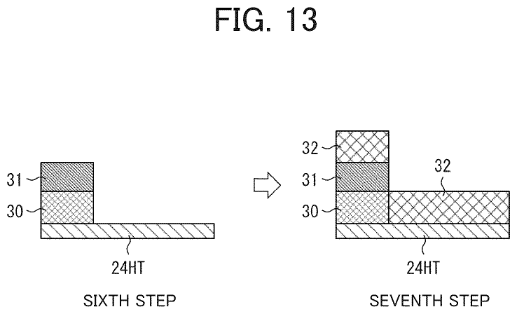

The following describes a second embodiment of the present disclosure on the basis of FIGS. 12 and 13. A red emission layer included in a red light-emitting element of a display device according to this embodiment is different from that described in the first embodiment in that the red emission layer in this embodiment is formed through process steps different from those for forming the red emission layer in the first embodiment. The others are the same as those described in the first embodiment. For convenience in description, components having the same functions as those of the components illustrated in the drawings related to the first embodiment will be denoted by the same signs, and their description will be omitted.

First through sixth steps illustrated in FIG. 12 constitute part of an emission-layer formation step according to the second embodiment, i.e., forming the red emission layer 24REM included in the red light-emitting element 5R of the display device 1 according to the first embodiment illustrated in FIG. 6.

The sixth step and a seventh step illustrated in FIG. 13 constitute the remaining part of the emission-layer formation step according to the second embodiment, i.e., forming the red emission layer 24REM included in the red light-emitting element 5R of the display device 1 according to the first embodiment illustrated in FIG. 6.

The fourth step illustrated in FIG. 12 constitutes a step of forming the graphene layer (first graphene layer) 30 that is performed immediately before the fifth step illustrated in FIG. 12, i.e., a nanoparticle-layer formation step. In the sixth step illustrated in FIG. 12, i.e., patterning the nanoparticle layer 31, the graphene layer (first graphene layer) 30 and the nanoparticle layer 31 undergo patterning into a predetermined shape through liftoff using the resist 60.

The first through fourth steps illustrated in FIG. 12, which are the same as the first through fourth steps illustrated in FIG. 10, will not be described here.

In the fifth step illustrated in FIG. 12, i.e., the nanoparticle-layer formation step, the nanoparticle layer 31 is formed onto the entire surface by using a nanoparticle solution containing the quantum dot QD or nanoparticle, and a first solvent (e.g., octane) capable of dispersing the quantum dot QD. That is, in the fifth step illustrated in FIG. 12, i.e., the nanoparticle-layer formation step, the nanoparticle layer 31 is formed so as to be in contact with the graphene layer (first graphene layer) 30 entirely.

Then, in the sixth step illustrated in FIG. 12, i.e., patterning the nanoparticle layer 31, the graphene layer (first graphene layer) 30 and the nanoparticle layer 31 undergo patterning into a predetermined shape through liftoff using the resist 60. In the sixth step illustrated in FIG. 12, i.e., patterning the nanoparticle layer 31, the resist 60 is exfoliated by the use of a remover liquid, an example of which is PGMEA, to separate the resist 60 from the graphene layer (first graphene layer) 30 formed on the resist 60 and from the nanoparticle layer 31, so that the graphene layer (first graphene layer) 30 and the nanoparticle layer 31 can undergo patterning into a predetermined shape.

Then, the graphene layer (second graphene layer) 32 is formed onto the entire surface in the seventh step illustrated in FIG. 13, i.e., forming the graphene layer (second graphene layer) 32, that is performed immediately after the sixth step illustrated in FIGS. 12 and 13, i.e., patterning the nanoparticle layer 31.

Through the foregoing process steps, the red emission layer 24REM provided with the quantum-dot layer including the quantum dots QD, which is the nanoparticle layer 31 including nanoparticles, the graphene layer (first graphene layer) 30, which is disposed under the quantum-dot layer, and the graphene layer (second graphene layer) 32, which is disposed over the quantum-dot layer, can be formed in a predetermined region on the hole transport layer 24HT, as illustrated in the seventh step in FIG. 13.

### Third Embodiment

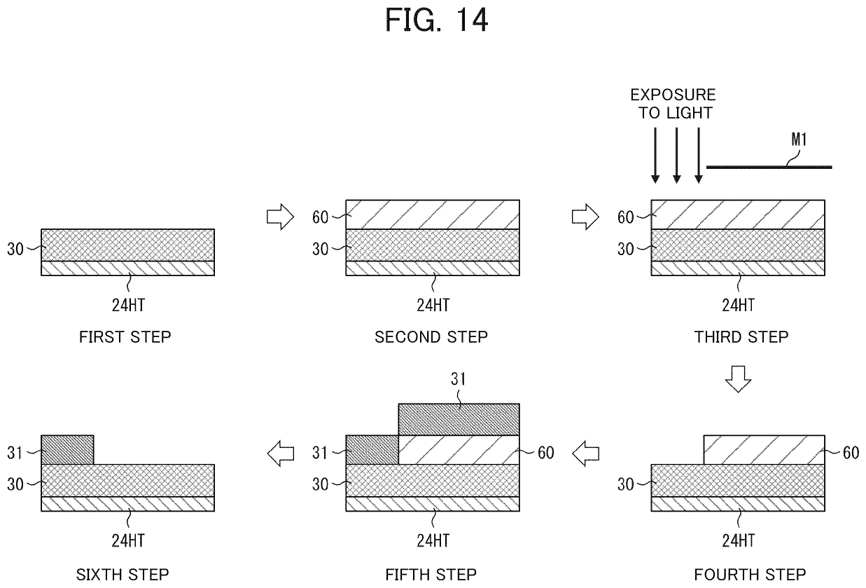

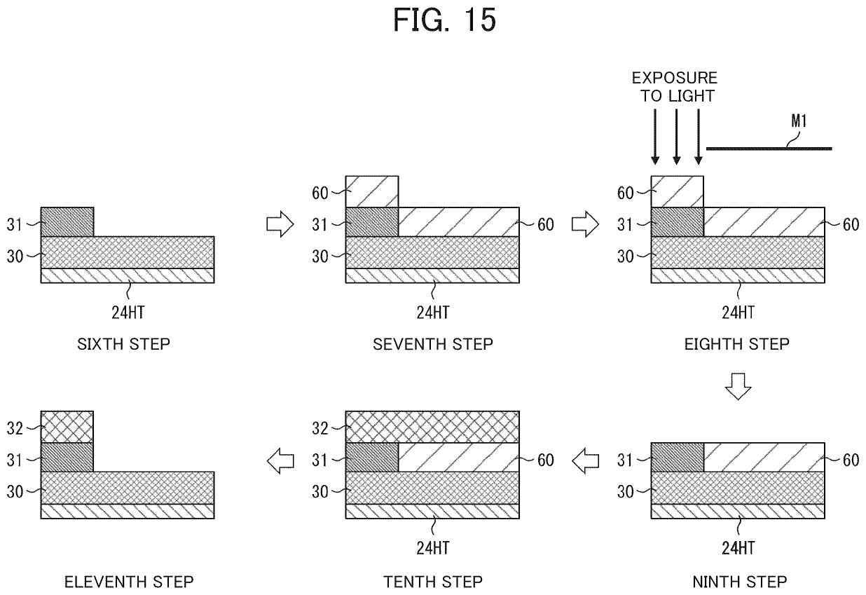

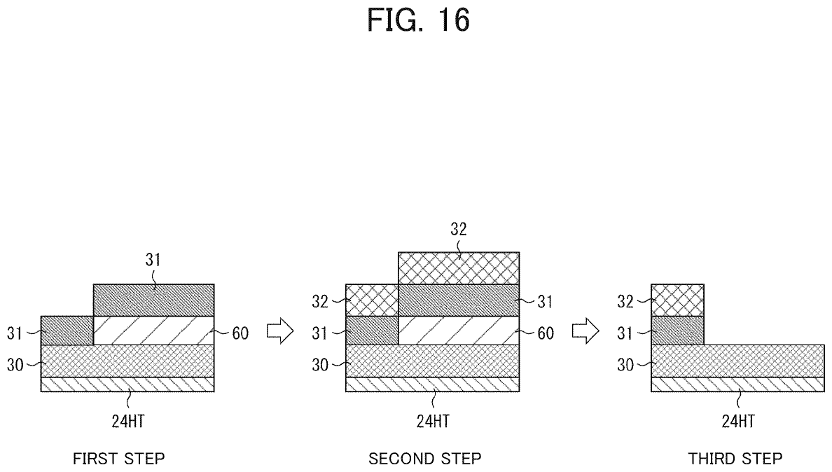

The following describes a third embodiment of the present disclosure on the basis of FIGS. 14 and 15. A red emission layer included in a red light-emitting element of a display device according to this embodiment is different from those described in the first and second embodiments in that the red emission layer in this embodiment is formed through process steps different from those for forming the red emission layer in the first and second embodiments. The others are the same as those described in the first and second embodiments. For convenience in description, components having the same functions as those of the components illustrated in the drawings related to the first and second embodiments will be denoted by the same signs, and their description will be omitted.

First through sixth steps illustrated in FIG. 14 constitute part of an emission-layer formation step according to the third embodiment, i.e., forming the red emission layer 24REM included in the red light-emitting element 5R of the display device 1 according to the first embodiment illustrated in FIG. 6.

The sixth step through eleventh steps illustrated in FIG. 15 constitute the remaining part of the emission-layer formation step according to the third embodiment, i.e., forming the red emission layer 24REM included in the red light-emitting element 5R of the display device 1 according to the first embodiment illustrated in FIG. 6.

First, in the first step illustrated in FIG. 14, i.e., forming the graphene layer (first graphene layer) 30, the graphene layer (first graphene layer) 30 is formed onto the entire surface of the hole transport layer 24HT.

Then, in the second step illustrated in FIG. 14, i.e., forming the resist 60, the resist 60 is formed onto the entire surface of the graphene layer (first graphene layer) 30.

Then, in the third step illustrated in FIG. 14, i.e., subjecting the resist 60 to exposure, the resist 60 provided on the graphene layer (first graphene layer) 30 undergoes exposure in a predetermined region by the use of the mask M1 with an opening through which the predetermined region is irradiated with exposure light.

Then, in the fourth step illustrated in FIG. 14, i.e., subjecting the resist 60 to development, the resist 60 undergoes development by the use of an alkali developing solution to remove the exposed predetermined region, thereby forming an opening in the predetermined region of the resist 60.

Then, in the fifth step illustrated in FIG. 14, i.e., a nanoparticle-layer formation step, the nanoparticle layer 31 is formed onto the entire surfaces of the resist 60 and graphene layer (first graphene layer) 30 by using a nanoparticle solution containing the quantum dot QD or nanoparticle, and a first solvent (e.g., octane) capable of dispersing the quantum dot QD. That is, in the fifth step illustrated in FIG. 14, i.e., the nanoparticle-layer formation step, the nanoparticle layer 31 is formed so as to be in contact with the graphene layer (first graphene layer) 30 partly.

Then, in the sixth step illustrated in FIG. 14, i.e., patterning the nanoparticle layer 31, the nanoparticle layer 31 undergoes patterning into a predetermined shape through liftoff using the resist 60. In the sixth step illustrated in FIG. 14, i.e., patterning the nanoparticle layer 31, the resist 60 is exfoliated with a remover liquid, an example of which is PGMEA, to separate the resist 60 and the nanoparticle layer 31 formed on the resist 60 from each other, so that the nanoparticle layer 31 can undergo patterning into a predetermined shape.

Then, the seventh through eleventh steps illustrated in FIG. 15 constitute a step of forming the graphene layer (second graphene layer) 32. In the step of forming the graphene layer (second graphene layer) 32, the graphene layer (second graphene layer) 32 undergoes patterning into a predetermined shape through liftoff using the resist 60.

In the seventh step illustrated in FIG. 15, i.e., forming the resist 60, which is performed after the sixth step illustrated in FIGS. 14 and 15, i.e., patterning the nanoparticle layer 31, the resist 60 is formed onto the entire surfaces of the graphene layer (first graphene layer) 30 and nanoparticle layer 31.

Then, in the eighth step illustrated in FIG. 15, i.e., subjecting the resist 60 to exposure, the resist 60 provided on the nanoparticle layer 31 undergoes exposure by the use of the mask M1.

Then, in the ninth step illustrated in FIG. 15, i.e., subjecting the resist 60 to development, the resist 60 provided on the nanoparticle layer 31 is removed through development by the use of an alkali developing solution.

Then, as illustrated in the tenth step in FIG. 15, the graphene layer (second graphene layer) 32 is formed onto the entire surfaces of the resist 60 and nanoparticle layer 31 by the use of a graphene oxide solution containing a graphene oxide having a functional group capable of coordinating with the nanoparticle QD included in the nanoparticle layer 31, and a second solvent (e.g., isopropyl alcohol or IPA for short) capable of dispersing the graphene oxide. It is noted that in this step, the graphene layer (second graphene layer) 32 is formed so as to be in contact with the nanoparticle layer 31 partly.

Then, in the eleventh step illustrated in FIG. 15, i.e., exfoliating the resist 60, the resist 60 is exfoliated with a remover liquid, an example of which is PGMEA, so that the resist 60 and the graphene layer (second graphene layer) 32 formed on the resist 60 can be separated from each other.

Through the foregoing process steps, the red emission layer 24REM provided with the quantum-dot layer including the quantum dots QD, which is the nanoparticle layer 31 including nanoparticles, the graphene layer (first graphene layer) 30, which is disposed under the quantum-dot layer, and the graphene layer (second graphene layer) 32, which is disposed over the quantum-dot layer, can be formed in a predetermined region on the hole transport layer 24HT, as illustrated in the eleventh step in FIG. 15.

### Fourth Embodiment

The following describes a fourth embodiment of the present disclosure on the basis of FIG. 16. A red emission layer included in a red light-emitting element of a display device according to this embodiment is different from that described in the first to third embodiments in that the red emission layer in this embodiment is formed through process steps different from those for forming the red emission layer in the first to third embodiment. The others are the same as those described in the first to third embodiments. For convenience in description, components having the same functions as those of the components illustrated in the drawings related to the first to third embodiments will be denoted by the same signs, and their description will be omitted.

First through third steps illustrated in FIG. 16 constitute part of an emission-layer formation step according to the fourth embodiment, i.e., forming the red emission layer 24REM included in the red light-emitting element 5R of the display device 1 according to the first embodiment illustrated in FIG. 6.

The first step illustrated in FIG. 16 is the same as the fifth step illustrated in FIG. 12 according to the third embodiment. Before the first step illustrated in FIG. 16, the first through fourth steps illustrated in FIG. 12 are performed. The first through fourth steps illustrated in FIG. 12, the fifth step illustrated in FIG. 12, and the first step illustrated in FIG. 16 will not be described here.

In the third step illustrated in FIG. 16, i.e., patterning the nanoparticle layer 31, the graphene layer (second graphene layer) 32 formed in the second step illustrated in FIG. 16, i.e., forming the graphene layer (second graphene layer) 32, which is performed after the first step illustrated in FIG. 16, i.e., the nanoparticle-layer formation step, and before the third step illustrated in FIG. 16, i.e., patterning the nanoparticle layer 31, and the nanoparticle layer 31 formed in the first step illustrated in FIG. 16, i.e., the nanoparticle-layer formation step, undergo patterning into a predetermined shape through liftoff using the resist 60.

Through the foregoing process steps, the red emission layer 24REM provided with the quantum-dot layer including the quantum dots QD, which is the nanoparticle layer 31 including nanoparticles, the graphene layer (first graphene layer) 30, which is disposed under the quantum-dot layer, and the graphene layer (second graphene layer) 32, which is disposed over the quantum-dot layer, can be formed in a predetermined region on the hole transport layer 24HT, as illustrated in the third step in FIG. 16.

### ADDITIONAL NOTE

The present disclosure is not limited to the foregoing embodiments. Various modifications can be made within the scope of the claims. An embodiment that is obtained in combination as appropriate with the technical means disclosed in the respective embodiments is also encompassed within the technical scope of the present disclosure. Furthermore, combining the technical means disclosed in the respective embodiments can form a new technical feature.

### INDUSTRIAL APPLICABILITY

The present disclosure is applicable to a light-emitting element, a display device including the light-emitting element, and a method for producing the light-emitting element, and a method for producing the display device.

1. A light-emitting element comprising:
an emission layer; and
a charge functional layer,
wherein at least one of the emission layer and the charge functional layer includes
a nanoparticle layer including a nanoparticle, and
at least one graphene layer being in contact with the nanoparticle layer, and including a graphene oxide having a functional group capable of coordinating with the nanoparticle.

2. The light-emitting element according to claim 1, wherein the functional group included in the graphene oxide includes a carboxyl group.

3. The light-emitting element according to claim 2, wherein the functional group included in the graphene oxide further includes one or more of a thiol group, an amino group, and a phosphonic group.

4. The light-emitting element according to claim 1, wherein
at least one of the emission layer and the charge functional layer further includes a crosslink molecule,
the crosslink molecule has one end including an acid functional group,
the crosslink molecule has another end including one or more of a carboxyl group, a thiol group, an amino group, and a phosphonic group, and
the graphene oxide and the nanoparticle are joined together via the crosslink molecule.

5. (canceled)

6. The light-emitting element according to claim 4, wherein the crosslink molecule includes three or more thiol groups.

7. The light-emitting element according to claim 1, wherein the graphene oxide has a maximum width ranging from 100 nm inclusive to 10 μm inclusive.

8. The light-emitting element according to claim 7, wherein the maximum width ranges from 300 nm inclusive to 5 μm inclusive.

9-11. (canceled)

12. The light-emitting element according to claim 1, wherein the at least one graphene layer has a thickness of 0.3 to 100 nm inclusive.

13. The light-emitting element according to claim 12, wherein the at least one graphene layer has a thickness of 0.3 to 5 nm inclusive.

14-16. (canceled)

17. The light-emitting element according to claim 1, wherein the graphene oxide is a reduced graphene oxide.

18. (canceled)

19. A method for producing a light-emitting element, comprising:
a nanoparticle-layer formation step of forming a nanoparticle layer by using a nanoparticle solution containing a nanoparticle and a first solvent;
at least one of a first graphene-layer formation step and a second graphene-layer formation step each being a step of forming a graphene layer by using a graphene oxide solution containing a second solvent and a graphene oxide having a functional group capable of coordinating with the nanoparticle, the first graphene-layer formation step being anterior to the nanoparticle-layer formation step, the second graphene-layer formation step being posterior to the nanoparticle-layer formation step; and
a nanoparticle-layer patterning step of patterning the nanoparticle layer into a predetermined shape,
wherein in the nanoparticle-layer formation step and the second graphene-layer formation step, both of which are performed after the first graphene-layer formation step, the nanoparticle layer and the graphene layer are formed so as to be in contact at least partly.

20. The method for producing the light-emitting element according to claim 19, wherein
in the first graphene-layer formation step, which is performed before the nanoparticle-layer formation step, the graphene layer undergoes patterning into a predetermined shape through liftoff using a resist,
in the nanoparticle-layer formation step, the nanoparticle layer is formed onto an entire surface, and
in the nanoparticle-layer patterning step, only the nanoparticle layer being in contact with the graphene layer patterned into the predetermined shape is caused to remain by etching using the first solvent.

21. The method for producing the light-emitting element according to claim 19, wherein in the nanoparticle-layer patterning step, the graphene layer formed in the first graphene-layer formation step that is performed immediately before the nanoparticle-layer formation step, and the nanoparticle layer formed in the nanoparticle-layer formation step undergo patterning into a predetermined shape through liftoff using a resist.

22. The method for producing the light-emitting element according to claim 19, wherein
in the first graphene-layer formation step, which is performed before the nanoparticle-layer formation step, the graphene layer is formed onto an entire surface, and
in the nanoparticle-layer patterning step, the nanoparticle layer undergoes patterning into a predetermined shape through liftoff using a resist.

23. The method for producing the light-emitting element according to claim 20, wherein in the second graphene-layer formation step that is performed immediately after the nanoparticle-layer patterning step, the graphene layer is formed onto an entire surface.

24. The method for producing the light-emitting element according to claim 20, wherein the second graphene-layer formation step, which is performed after the nanoparticle-layer patterning step, only the graphene layer being in contact with the nanoparticle layer is caused to remain by liftoff using a resist.

25. The method for producing the light-emitting element according to claim 22, wherein in the nanoparticle-layer patterning step, the graphene layer formed in the second graphene-layer formation step that is performed after the nanoparticle-layer formation step and before the nanoparticle-layer patterning step, and the nanoparticle layer formed in the nanoparticle-layer formation step undergo patterning into a predetermined shape through liftoff using a resist.

26. The method for producing the light-emitting element according to claim 19, further comprising a cross-linking-agent processing step of performing processing by using a cross-linking agent having one end including an acid functional group, and another end including one or more of a carboxyl group, a thiol group, an amino group, and a phosphonic group; and
a step of curing the cross-linking agent that is performed after the cross-linking-agent processing step, wherein
the cross-linking-agent processing step is performed on at least one of
a stack of the graphene layer formed in the first graphene-layer formation step, which is performed before the nanoparticle-layer formation step, and the nanoparticle layer, and
a stack of the nanoparticle layer and the graphene layer formed in the second graphene-layer formation step, which is performed after the nanoparticle-layer formation step, and wherein
at least one of light irradiation and heating is performed in the step of curing the cross-linking agent.

27-28. (canceled)

29. The method for producing the light-emitting element according to claim 26, further comprising a rinse step that is performed after the step of curing the cross-linking agent.

30. (canceled)

31. The method for producing the light-emitting element according to claim 19, wherein the graphene oxide is a graphene oxide undergone reduction.

32. (canceled)
